(19) United States
(12) Patent Application Publication
(10) Pub. No.: US 2024/0120223 A1
(43) Pub. Date: Apr. 11, 2024

(54) UNIFIED LATCH FOR WAFER CASSETTES

(71) Applicant: ENTEGRIS, INC., Billerica, MA (US)

(72) Inventors: Mohamad Zakaria Abd Mutholib, Kulim Kedah (MY); Hang Khim Tan, Bukit Mertajam (MY)

(21) Appl. No.: 18/379,060

(22) Filed: Oct. 11, 2023

Related U.S. Application Data
(60) Provisional application No. 63/441,345, filed on Jan. 26, 2023.
(60) Provisional application No. 63/415,182, filed on Oct. 11, 2022.

(51) Int. Cl. H01L 21/673

(52) U.S. Cl. CPC H01L 21/67373

(57) ABSTRACT

In wafer containers, a latching mechanism is provided to secure a wafer cassette within the container. The latching mechanism is driven by contact between an inner surface of the dome of the pod to contact the wafer cassette at a horizontal bar provided in the wafer cassette. The latching mechanism includes a dome contact element configured to contact the inner surface of the dome. The latching mechanism further is configured to retract and not overlap with the horizontal bar when not in contact with the dome. The latching mechanism is incorporated into or attached to the door.

### FIELD

This disclosure is directed to latches for securing wafer cassettes within wafer containers, particularly by contacting the cassette at the horizontal bar.

### BACKGROUND

Wafers such as semiconductor wafers can be stored in cassettes. The cassettes are placed into containers which include a dome and a door. To reduce or prevent movement, cassette hold down features can be provided on the dome or one or more cassette hold down members can be installed between the dome and the cassette. The interior features of the dome and the features on the cassette that can be engaged by a hold down are not standardized and can vary significantly between manufacturers, product lines, generations of products, and the like.

### SUMMARY

This disclosure is directed to latches for securing wafer cassettes within wafer containers, particularly by contacting the cassette at the horizontal bar.

By securing the cassette through contact with a standard feature such as the horizontal bar of the wafer cassette, latching mechanisms can provide a more broadly applicable solution, less subject to product-specific design changes. Further, the latching mechanisms according to embodiments automatically extend when the dome and door are joined and retract when the dome is removed. This facilitates the use of wafer containers including the latching mechanism with automation, which does not need to handle or account for potentially different cassette hold down structures. The latching mechanisms further have a profile which does not interfere with storage of wafers within the wafer cassette. The latching mechanisms can further be incorporated into existing wafer containers by attaching the latching mechanism to a door of the wafer container.

In an embodiment, a wafer container includes a dome defining a space configured to accommodate a wafer cassette, the dome including an inner surface and a door opening. The wafer container further includes a door configured to be received in the door opening, the door including a latching mechanism. The latching mechanism includes a dome contact and a cassette contact, and the latching mechanism is configured such that when the inner surface of the dome is in contact with the dome contact, the cassette contact is driven to contact the wafer cassette, and when the inner surface of the dome does not contact the dome contact, the latch does not overlap with the wafer cassette.

In an embodiment, the dome contact is a roller element. In an embodiment, the roller element includes a core made of a first material and an outer portion made of a second material, the second material relatively softer than the first material.

In an embodiment, the cassette contact is configured to contact the wafer cassette at a horizontal bar included in the wafer cassette.

In an embodiment, the latching mechanism includes a base, a latching arm, where the dome contact is disposed at a first end of the latching arm and the cassette contact is disposed at a second end of the latching arm, and a plurality of links, each rotatably connected to each of the base and the latching arm. In an embodiment, the base is joined to the door. In an embodiment, the wafer container further includes a biasing spring configured to contact the latching arm.

In an embodiment, the latching mechanism includes a base including a channel configured to receive the dome contact, a latching arm including the cassette contact, and a link rotatably connected to each of the base and the latching arm. The base includes a pin configured to interface with the latching arm. In an embodiment, the latching mechanism further comprises a guide roller, the guide roller disposed in the channel.

In an embodiment, the latching mechanism includes a base defining a channel, a latching arm including the cassette contact, a link, where the dome contact is attached to the link and the link is rotatably connected to each of the base and the latching arm, and a guide roller, the guide roller attached to the latching arm, the guide roller configured to travel within the channel.

In an embodiment, the latching mechanism includes a base, a driving arm, where the dome contact is attached to the driving arm, and a latching arm rotatably connected to the base. The latching arm includes the cassette contact. The driving arm and the latching arm are joined by a cam structure, the cam structure including a projection and a groove and configured so as to drive rotation of the latching arm between an unlatched position and a latched position.

In an embodiment, a method of securing a wafer cassette within a container includes driving a latching mechanism by way of contact between a dome contact of said latching mechanism and an inner surface of a dome such that a cassette contact is brought into contact with the wafer cassette.

In an embodiment, the method further includes retracting the cassette contact such that the cassette contact does not overlap the wafer cassette when the dome is removed from contact with the dome contact.

In an embodiment, the latching mechanism is included in a door of the container.

In an embodiment, the cassette contact contacts the wafer cassette at a horizontal bar included in the wafer cassette.

In an embodiment, the latching mechanism includes a base, a latching arm, where the dome contact is disposed at a first end of the latching arm and the cassette contact is disposed at a second end of the latching arm, and a plurality of links. Each link is rotatably connected to each of the base and the latching arm.

In an embodiment, the latching mechanism includes a base, the base including a channel configured to receive the dome contact, a latching arm including the cassette contact, and a link. The link is rotatably connected to each of the base and the latching arm. The base includes a pin configured to interface with the latching arm. In an embodiment, the latching mechanism further comprises a guide roller disposed in the channel.

In an embodiment, the latching mechanism includes a base defining a channel, a latching arm including the cassette contact, a link, and guide roller. The dome contact is attached to the link and the link is rotatably connected to each of the base and the latching arm. The guide roller is attached to the latching arm, the guide roller configured to travel within the channel.

In an embodiment, the latching mechanism includes a base, a driving arm, where the dome contact is attached to the driving arm, and a latching arm rotatably connected to the base. The latching arm includes the cassette contact. The driving arm and the latching arm are joined by a cam structure including a projection and a groove. The cam is configured to drive rotation of the latching arm between an unlatched position and a latched position.

### DRAWINGS

FIG. 1 shows a wafer container according to an embodiment.

FIG. 2A shows a sectional view of a wafer container when a latching mechanism according to an embodiment is in an unlatched position.

FIG. 2B shows a sectional view of the wafer container of FIG. 2A when the latching mechanism according to an embodiment is in a latched position.

FIG. 3A shows a sectional view of a wafer container when a latching mechanism according to an embodiment is in an unlatched position.

FIG. 3B shows a sectional view of the wafer container of FIG. 3A when the latching mechanism according to an embodiment is in a latched position.

FIG. 4A shows a sectional view of a wafer container when a latching mechanism according to an embodiment is in an unlatched position.

FIG. 4B shows a sectional view of the wafer container of FIG. 4A when the latching mechanism according to an embodiment is in a latched position.

FIG. 5A shows a sectional view of a wafer container when a latching mechanism according to an embodiment is in an unlatched position.

FIG. 5B shows a sectional view of the wafer container of FIG. 5A when the latching mechanism according to an embodiment is in a latched position.

FIG. 6A shows a sectional view of a wafer container when a latching mechanism according to an embodiment is in an unlatched position.

FIG. 6B shows a sectional view of the wafer container of FIG. 6A when the latching mechanism according to an embodiment is in a latched position.

FIG. 7 shows an exploded view of a latch mechanism according to an embodiment.

### DETAILED DESCRIPTION

This disclosure is directed to latches for securing wafer cassettes within wafer containers, particularly by contacting the cassette at the horizontal bar.

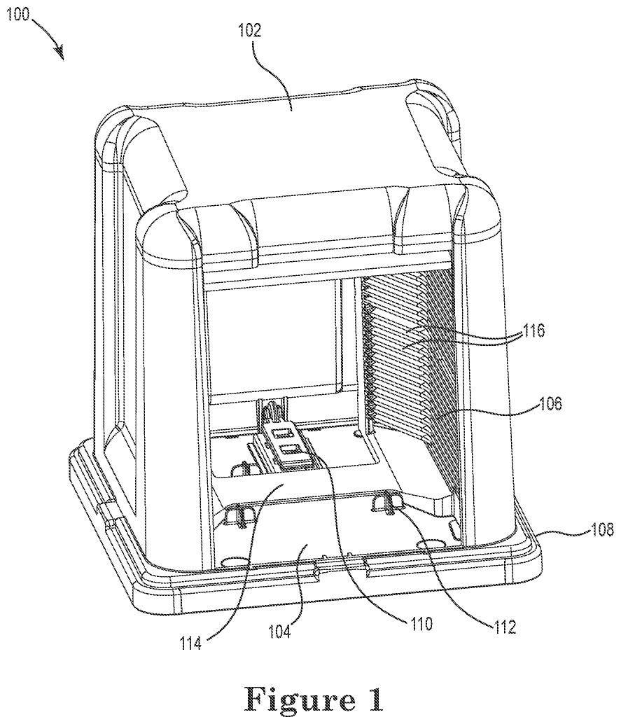

FIG. 1 shows a wafer container according to an embodiment. Wafer container 100 includes dome 102, door 104, and wafer cassette 106.

The dome 102 is configured to define an internal space capable of accommodating the wafer cassette 106. The dome 102 has a door opening 108 configured to receive the door 104 such that the door 104 encloses the internal space of dome 102.

Door 104 is configured to be placed into door opening 108. The door 104 includes a latching mechanism 110. The latching mechanism 110 is configured such that when the door 104 and dome 102 are combined, an internal surface of dome 102 contacts part of latching mechanism 110, driving the latching mechanism 110 from an unlatched state where it does not contact or overlap with wafer cassette 106 to a latched state where it contacts the wafer cassette 106 to secure the position of the wafer cassette within the wafer container 100. Latching mechanism 110 can contact the wafer cassette 106 at any suitable position such that the wafer cassette 106 can be secured at least partially by way of such contact. The latching mechanism 110 can contact wafer cassette 106 at, for example, any standard feature of the wafer cassette 106, flanges, tabs, projections, included in wafer 106, or the like. In an embodiment, the latching mechanism 110 can contact the wafer cassette at horizontal bar 114 included in the wafer cassette 106. Door 104 can further include one or more alignment features 112 configured to contact the wafer cassette 106 when the wafer container 100 is assembled.

Wafer cassette 106 is configured to store one or more wafers. Wafer cassette 106 can include one or more wafer slots 112. A horizontal bar 114 can extend across wafer cassette 106, for example at a bottom thereof.

In use, the wafer cassette 106 can be placed onto the door 104. The placement of wafer cassette 106 can be guided by one or more alignment features 112 on the door 104. The dome 102 can then be placed onto the door 104 and wafer cassette 106, such that the wafer cassette 106 is within the internal space of dome 102 when door 104 is received within door opening 108. As the dome 102 and door 104 are combined, an internal surface of dome 102 contacts the latching mechanism 110. The contact of the dome 102 with latching mechanism 110 drives the latching mechanism to bring a contact surface into contact with wafer cassette 106 to secure wafer cassette 106. In an embodiment, the contact surface can come into contact with the horizontal bar 114 of wafer cassette 106. When pod dome 102 is separated from pod door 104, the inner surface of the pod dome 102 no longer contacts the latching mechanism 110. The latching mechanism 110 can be configured to return to the unlatched position when the pod dome 102 no longer contacts the latching mechanism 110.

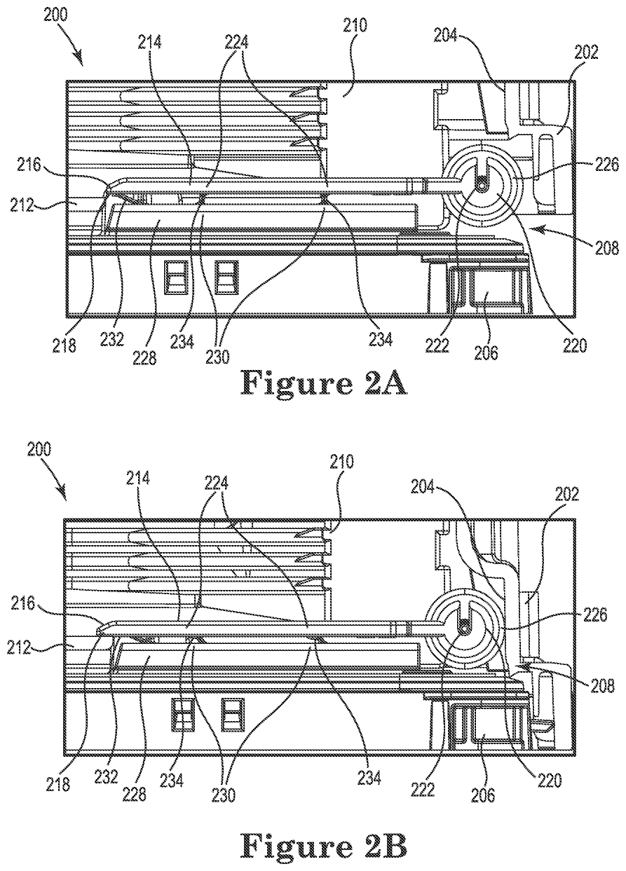

FIG. 2A shows a sectional view of a wafer container when a latching mechanism according to an embodiment is in an unlatched position. Wafer container 200 includes dome 202 having internal surface 204 and door 206 including latching mechanism 208. Wafer container 200 further includes wafer cassette 210 placed onto the door 206, the wafer cassette 210 having horizontal bar 212. In the view shown in FIG. 2A, the dome 202 is apart from the door 206 and the latching mechanism 208 is in an unlatched position where it does not overlap with the horizontal bar 212.

The latching mechanism 208 includes a latch arm 214. The latch arm 214 includes a first end 216 where a contact surface 218 is provided. The latch arm 214 further includes a second end 220 where a dome contact retainer 222 is provided. A plurality of latch arm link connections 224 are provided on the latch arm 214. Dome contact element 226 is held in the dome contact retainer 222. The latching mechanism further includes a base 228. The base 228 includes base link connections 230. Biasing spring 232 is provided on base 228. A plurality of links 234 are provided, each link 234 connected to a latch arm link connection 224 and to a base link connection 230.

Latch arm 214 is configured to be movable between an unlatched position allowing the wafer cassette 210 to be readily positioned on or removed from door 206, and a latched position where the latch arm 214 secures the wafer cassette 210 by way of contact with the horizontal bar 212 of the wafer cassette 210. Latch arm 214 has a first end 216 including contact surface 218. Contact surface 218 can be formed integrally with latch arm 214 or be an additional element attached to the first end 216 of latch arm 214. The contact surface 218 is configured to contact the horizontal bar 212 to secure the wafer cassette 210. Contact surface 218 can be configured to contact wafer cassette 210 at any suitable location such that wafer cassette 210 can be secured, with one non-limiting example being horizontal bar 212. The latch arm 214 further includes second end 220, opposite the first end 216. A dome contact retainer 222 is disposed at second end 222. Dome contact retainer 222 can include, for example, an opening, recess, groove, or the like configured to receive projections of the dome contact element 226 such as an axle of the dome contact element 226.

Arm link connections 224 are provided along a length of latch arm 214 so as to allow the latch arm 214 to be connected to each of a plurality of links 234. The arm link connections can be any suitable feature allowing a rotatable connection. In the non-limiting example shown in FIGS. 2A and 2B, the arm link connections 224 include openings in latch arm 214 and cylindrical extensions across said openings. The cylindrical extensions are sized such that clips provided at the ends of a link 234 can engage with the cylindrical extensions, thus providing a rotatable connection between the link 234 and the latch arm 214 at the arm link connection 224.

Dome contact element 226 is an element configured to contact the internal surface 204 of the dome 202. Dome contact element 226 can be any suitable contact element, such as an element including a camming surface or a fixed curved surface, a roller, or the like. The dome contact element 226 can be, for example, a roller. In an embodiment, the dome contact element 226 includes at least one rounded surface, for example, being circular, oval, or any other shape including a rounded surface. In an embodiment, the dome contact element 226 is circular in shape. In an embodiment, the dome contact element 226 is a single piece. In an embodiment, the dome contact element 226 includes at least two different materials, for example a core including a relatively harder and/or more rigid core material and a contact surface made of a relatively softer and/or more flexible contact surface material. In an embodiment, the contact surface can be overmolded onto the core. In an embodiment, the contact surface material can be selected from elastomers such as thermoplastic elastomer, silicone, or the like. Dome contact element 226 can be configured to be accommodated in or retained by dome contact retainer 222, for example having outward projections forming an axle allowing the dome contact element 226 to be retained in dome contact retainer 222 and allowing dome contact element 226 to be rotated while retained. In an embodiment, dome contact element 226 is formed integrally with latch arm 214.

Base 228 is configured to attach latching mechanism 208 to the door 206. The base 228 can be attached to door 206, formed integrally with door 206, or include some portions attached to door 206 and other portions formed integrally with door 206. The base 228 can be sized such that a maximum height of the latching mechanism 228 above a surface of door 206 on which the base 228 is disposed is such that the latching mechanism 208 would not interfere with wafers placed in the wafer cassette 210. In an embodiment, the base 228 is sized such that a height of the latching mechanism is equal to or less than 0.8 inches (approximately 2 centimeters).

Base link connections 230 are provided on base 228. The base link connections can be cylindrical bars extending across an open space provided in base 228. The cylindrical bars can be sized such that clips provided on the links 234 can engage with the cylindrical bars to attach one end of a link 234 to one of the base link connections 230. The attachment of the links 234 to the corresponding base link connections 230 can be such that the links 234 are able to rotate, for example in response to forces moving the latch arm 214 to which the links 234 are also connected to.

Biasing spring 232 is provided on base 228. Biasing spring 232 can be any suitable spring for applying a force to the latch arm 214, such as a spring arm, leaf spring, coil spring, or the like. The biasing spring 232 can be a separate element attached to base 228, or formed integrally with base 228. The biasing spring is configured to contact the latch arm 214. The biasing spring is configured to drive the latch arm 214 into an unlatched state where the latch arm 214 does not overlap with the horizontal bar 212. In the embodiment shown in FIG. 2A, the force applied by the biasing spring 232 drives latch arm 214 upwards. Upwards movement of the latch arm 214 is translated in part into outward movement of the latch arm 214 into the unlatched state by the fixed length of links 234 and the rotation thereof.

Links 234 join the latch arm 232 to the base 228. The links 234 are rotatable at each of the connections to the latch arm 232 and base 228. In an embodiment, the links 234 each include a first clip that attached to one of arm link connections 224 at a first end, and a second clip at an opposite end of the link 234 that is attached to one of base link connections 230. The links 234 each have a fixed length. The fixed length and rotatable connections of links 234 control the movement of latch arm 214 relative to the base 228 such that the latch arm 214 can be moved between the latched and unlatched positions.

FIG. 2B shows a sectional view of the wafer container of FIG. 2A when the latching mechanism according to an embodiment is in a latched position. In the latched position shown in FIG. 2B, the internal surface 204 of dome 202 contacts dome contact element 226. The contact between internal surface 204 and dome contact element 226 drives dome contact element 226 inwards. The connection of the dome contact element 226 to the latch arm 214 results in the latch arm 214 also being driven inwards. The inward movement of latch arm 214 causes the links 234 to rotate, pulling the latch arm 214 downwards as the latch arm 214 moves inwards. The force overcomes the force provided by the biasing spring 232, thus bringing contact surface 218 over and downwards onto the horizontal bar 212 of the wafer cassette 210. The contact surface 218 thus secures the position of the wafer cassette 210 on the door 206. When dome 202 is removed from door 206, the biasing spring drives latch arm 214 downwards, causing rotational movement defined by the links 234, such that the latch arm 214 is returned to the unlatched position where it does not overlap horizontal bar 212 and the wafer cassette 210 can be removed from door 206 without interference from latching mechanism 208.

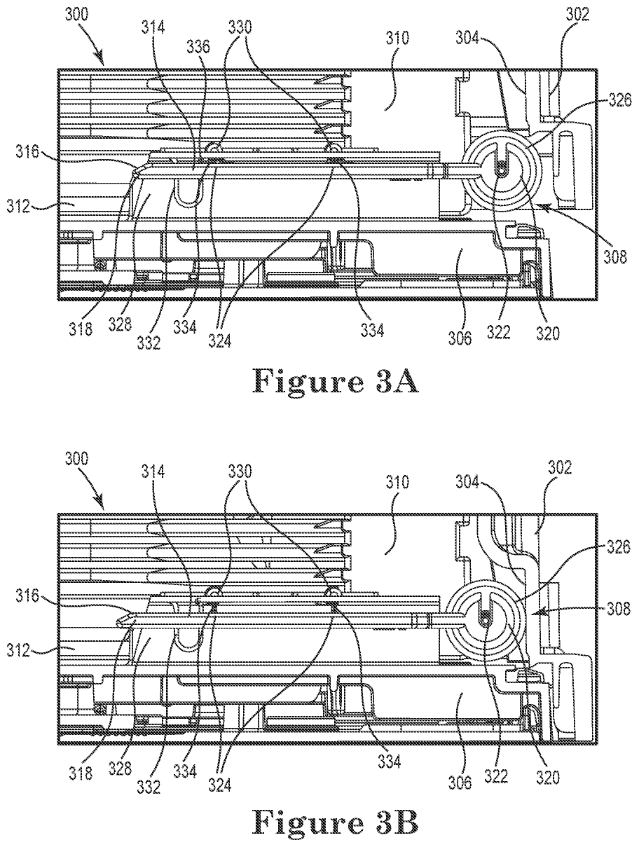

FIG. 3A shows a sectional view of a wafer container when a latching mechanism according to an embodiment is in an unlatched position. Wafer container 300 includes dome 302 having internal surface 304 and door 306 including latching mechanism 308. Wafer container 300 further includes wafer cassette 310 placed onto the door 306, the wafer cassette 310 having horizontal bar 312. In the view shown in FIG. 3A, the dome 302 is apart from the door 306 and the latching mechanism 308 is in an unlatched position where it does not overlap with the horizontal bar 312.

The latching mechanism 308 includes a latch arm 314. The latch arm 314 includes a first end 316 where a contact surface 318 is provided. The latch arm 314 further includes a second end 320 where a dome contact retainer 322 is provided. A plurality of latch arm link connections 324 are provided on the latch arm 314. Dome contact element 326 is held in the dome contact retainer 322. The latching mechanism further includes a base 328. The base 328 includes base link connections 330. Biasing spring 332 is provided on base 328. A plurality of links 334 are provided, each link 334 connected to a latch arm link connection 324 and to a base link connection 330.

Latch arm 314 is configured to be movable between an unlatched position allowing the wafer cassette 310 to be readily positioned on or removed from door 306, and a latched position where the latch arm 314 secures the wafer cassette 310 by way of contact with the horizontal bar 312 of the wafer cassette 310. Latch arm 314 has a first end 316 including contact surface 318. Contact surface 318 can be formed integrally with latch arm 314 or be an additional element attached to the first end 316 of latch arm 314. Contact surface 318 can be configured to contact wafer cassette 310 at any suitable location such that wafer cassette 310 can be secured. In an embodiment, the contact surface 318 is configured to contact the horizontal bar 312 to secure the wafer cassette 310. Contact surface 318 can include a bevel, a sloping surface, a step, shoulder, ledge, or any other suitable feature such that contact surface 318 can effectively retain the horizontal bar 312 despite the latch arm 314 being moved upwards as latch arm 314 is driven into the latched position. The latch arm 314 further includes second end 320, opposite the first end 316. A dome contact retainer 322 is disposed at second end 322. Dome contact retainer can include, for example, an opening, recess, groove, or the like configured to receive projections of the dome contact element 326 such as an axle of the dome contact element 326.

Arm link connections 324 are provided along a length of latch arm 314 so as to allow the latch arm 314 to be connected to each of a plurality of links 334. The arm link connections can be any suitable feature allowing a rotatable connection. In the non-limiting example shown in FIGS. 3A and 3B, the arm link connections 324 include openings in latch arm 314 and cylindrical extensions across said openings. The cylindrical extensions are sized such that clips provided at the ends of a link 334 can engage with the cylindrical extensions, thus providing a rotatable connection between the link 334 and the latch arm 314 at the arm link connection 324.

Dome contact element 326 is an element configured to contact the internal surface 304 of the dome 302. Dome contact element 326 can be any suitable contact element, such as an element including a camming surface or a fixed curved surface, a roller, or the like. In an embodiment, the dome contact element 326 includes at least one rounded surface, for example, being circular, oval, or any other shape including a rounded surface. In an embodiment, the dome contact element 326 is circular in shape. In an embodiment, the dome contact element 326 is a single piece. In an embodiment, the dome contact element 326 includes at least two different materials, for example a core including a relatively harder and/or more rigid core material and a contact surface made of a relatively softer and/or more flexible contact surface material. In an embodiment, the contact surface can be overmolded onto the core. In an embodiment, the contact surface material can be selected from elastomers such as thermoplastic elastomer, silicone, or the like. Dome contact element 326 is configured to be accommodated in or retained by dome contact retainer 322, for example having outward projections forming an axle allowing the dome contact element 326 to be retained in dome contact retainer 322 and allowing dome contact element 326 to be rotated while retained.

Base 328 is configured to attach latching mechanism 308 to the door 306. The base 328 can be attached to door 306, formed integrally with door 306, or include some portions attached to door 306 and other portions formed integrally with door 306. Base 328 is sized and configured to provide an open space through which the latch arm 314 can travel between latched and unlatched positions. The base 328 can be sized such that a maximum height of the latching mechanism 328 above a surface of door 306 on which the base 328 is disposed is such that the latching mechanism 308 would not interfere with wafers placed in the wafer cassette 310. In an embodiment, the base 328 is sized such that a height of the latching mechanism is equal to or less than 0.8 inches (approximately 2 centimeters).

Base link connections 330 are provided on base 328. The base link connections can be cylindrical bars extending across an open space provided in base 328. The cylindrical bars can be sized such that clips provided on the links 334 can engage with the cylindrical bars to attach one end of a link 334 to one of the base link connections 330. The attachment of the links 334 to the corresponding base link connections 330 can be such that the links 334 are able to rotate, for example in response to forces moving the latch arm 314 to which the links 334 are also connected to.

Biasing spring 332 is provided on base 328. Biasing spring 332 can be any suitable spring for applying a force to the latch arm 314, such as a spring arm, leaf spring, coil spring, or the like. The biasing spring 332 can be a separate element attached to base 328, or formed integrally with base 328. The biasing spring is configured to contact the latch arm 314. The biasing spring is configured to drive the latch arm 314 into an unlatched state where the latch arm 314 does not overlap with the horizontal bar 312. In the embodiment shown in FIG. 3A, the force applied by the biasing spring 332 drives latch arm 314 outwards into the unlatched state. The biasing spring 332 can interface with the latch arm 314 at an interface feature 336 provided on latch arm 314, such as a tab including a projection or a recess, a contact surface configured to receive a part of the biasing spring 332, or another suitable feature allowing the biasing spring to reliably act on latch arm 314.

Links 334 join the latch arm 314 to the base 328. The links 334 are rotatable at each of the connections to the latch arm 314 and base 328. In an embodiment, the links 334 each include a first clip that attached to one of arm link connections 324 at a first end, and a second clip at an opposite end of the link 334 that is attached to one of base link connections 330. The links 334 each have a fixed length. The fixed length and rotatable connections of links 334 control the movement of latch arm 314 relative to the base 328 such that the latch arm 314 can be moved between the latched and unlatched positions.

FIG. 3B shows a sectional view of the wafer container of FIG. 3A when the latching mechanism according to an embodiment is in a latched position. In the latched position shown in FIG. 3B, the internal surface 304 of dome 302 contacts dome contact element 326. The contact between internal surface 304 and dome contact element 326 drives dome contact element 326 inwards. The connection of the dome contact element 326 to the latch arm 314 results in the latch arm 314 also being driven inwards. The inward movement of latch arm 314 causes the links 334 to rotate, pulling the latch arm 314 downwards as the latch arm 314 moves inwards. The force overcomes the force provided by the biasing spring 332, thus bringing contact surface 318 over the horizontal bar 312 of the wafer cassette 310. The contact surface 318 thus secures the position of the wafer cassette 310 on the door 306. When dome 302 is removed from door 306, the biasing spring drives latch arm 314 upwards, causing rotational movement defined by the links 334, such that the latch arm 314 is returned to the unlatched position where it does not overlap horizontal bar 312 and the wafer cassette 310 can be removed from door 306 without interference from latching mechanism 308.

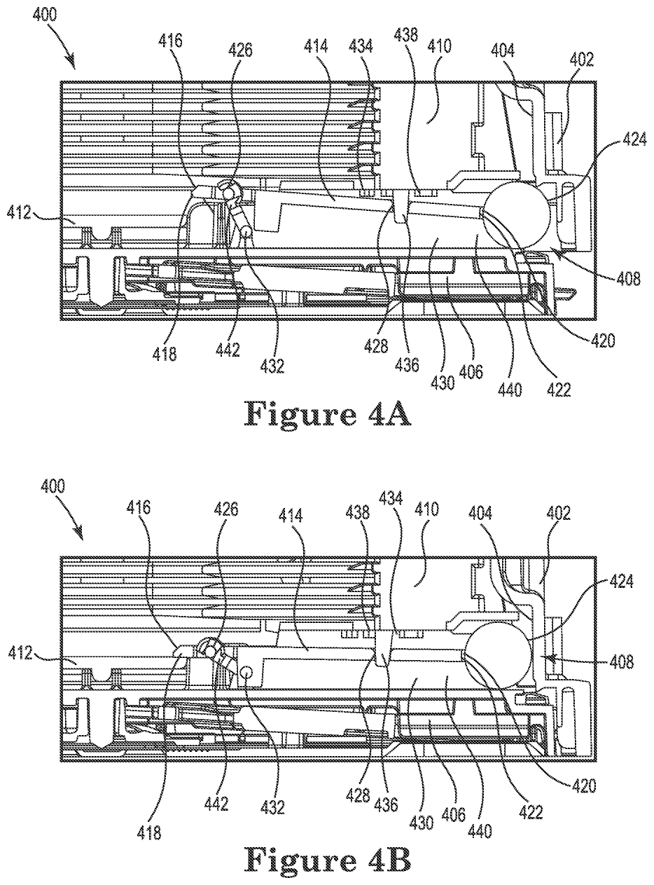

FIG. 4A shows a sectional view of a wafer container when a latching mechanism according to an embodiment is in an unlatched position. Wafer container 400 includes dome 402 including internal surface 404, door 406 including latching mechanism 408, and wafer cassette 410 including horizontal bar 412. The latching mechanism 408 includes a latch arm 414 including a first end 416 having a contact surface 418. The latch arm 414 further includes a second end 420 having dome contact retainer 422. Dome contact element 424 is attached to latch arm 414 at dome contact retainer 422. The latch arm 414 further includes an arm link attachment 426 and an aperture 428. The latching mechanism further includes a base 430 including a base link attachment 432, and a biasing pin 434 including a projection 436 and spring 438. A link 442 is connected to each of the latch arm 414 and the base 430.

The latching mechanism 408 includes latch arm 414 including a first end 416 having a contact surface 418. Contact surface 418 is configured to contact the wafer cassette 410 when the latching mechanism is in the latched position. Contact surface 418 can be configured to contact wafer cassette 410 at any suitable location such that wafer cassette 410 can be secured, with one non-limiting example being horizontal bar 412. The latching mechanism 408 further includes a second end 420, where dome contact element 424 is attached. In an embodiment, a dome contact retainer 422 is at second end 420. Dome contact element 424 is attached to latch arm 414, for example at dome contact retainer 422. Dome contact element 424 can be any suitable contact element, such as an element including a camming surface or a fixed curved surface, a roller, or the like. In an embodiment, dome contact element 424 includes at least two different materials, for example a core including a harder or more rigid core material and a softer or more flexible contact surface. In an embodiment, the contact surface can be overmolded onto the core. In an embodiment, the contact surface material may be selected from one or more of the elastomers of the following list: thermoplastic elastomer, silicone, or the like.

Arm link attachment 426 is configured to allow attachment of link 442 to latch arm 414. The arm link attachment 426 can be any suitable structure allowing mechanical attachment of the link 442 to latch arm 414, for example a cylinder surrounded by an opening, allowing a clip included in link 442 to attach to arm link attachment 426. In an embodiment, arm link attachment 426 can be a clip or socket configured to receive a portion of link 442. The connection of arm link attachment 426 to link 442 can be such that link 442 and latch arm 414 can rotate relative to one another.

Latch arm 414 includes aperture 428. Aperture 428 is configured to receive projection 436 included in the biasing pin 434. In an embodiment, aperture 428 can have rounded or beveled edges, for example to facilitate insertion of the projection 436 of biasing pin 434 into the aperture 428. Aperture 428 is formed in the latch arm 414 such that the projection 436 of biasing pin 434 can apply force to the latch arm 414, for example to drive the latch arm 414 towards the unlatched state when no force is applied to the latch arm by way of dome contact element 424.

Latching mechanism 408 further includes base 430. Base 430 is provided on door 406. In an embodiment, base 430 has a maximum height above the door 406 of 0.8 inches or less. The base 430 defines channel 440. Channel 440 is configured such that the dome contact element 424 doattachment 432, which can be any suitable structure allowing the rotatable connection of link 442 to the base 430. The base link attachment 432 can be, for example, a cylindrical member with openings surrounding it to allow attachment of a clip, a clip or socket configured to receive a portion of link 442, or the like.

Base 430 further includes a biasing pin 434, configured to return the latch arm 414 to the unlatched position when other forces are not acting on the latch arm 414. The biasing pin 434 includes a projection 436 and spring 438. Projection 436 is configured to be received in aperture 428 provided on latch arm 414. The projection 436 is disposed on spring 438. Spring 438 is configured to allow the deflection of projection 436 when other forces are applied, for example when dome 402 contacts the dome contact element 424, and to provide force returning projection 436 to a position where the latch arm 414 is in an unlatched position. Spring 438 can be any suitable spring, for example one or more spring arms. The spring 438 can be a separate spring attached to base 430 or formed integrally with base 430. The projection 436 can be an element separate from spring 438 and attached thereto, or formed integrally with spring 438. In an embodiment, the base 430, spring 438, and projection 436 are all formed integrally with one another. In an alternative embodiment, the relative positions of aperture 428 and projection 436 can be reversed, with the projection 436 extending from latching arm 414 and the aperture 428 being defined in material attached to or included along the spring 438. In another alternative embodiment, the spring 438 can alternatively be included in the latch arm 414 with one of projection 436 or material defining aperture 428 being disposed on the spring 438, with the other of projection 436 or material defining aperture 428 being provided in a fixed position on base 430.

Link 442 is rotatably attached to latch arm 414 at arm link attachment 426 and rotatably attached to base 430 at base link attachment 432. Link 442 is configured to control the movement of latch arm 414 relative to base 430 when force is applied to the latch arm 414 by contact between the dome 402 and dome contact element 424 and/or by the biasing pin 434. The link 442 can be rigid and have a fixed length. The attachments of link 442 to the latch arm 414 and the base 430 can be at opposing ends of link 442. Link 442 can include any suitable structures to engage with and rotatably attach to arm link attachment 426 and base link attachment 432, such as clips, sockets, or corresponding engagement features such as a ball joint, a cylindrical portion having adjacent openings, or the like.

FIG. 4B shows a sectional view of the wafer container of FIG. 4A when the latching mechanism according to an embodiment is in a latched position. When the dome 402 is attached to the door 406, the internal surface 404 comes into contact with dome contact element 424, driving dome contact element 424 to move within channel 440 and thus also driving latch arm 414 inwards. The force moving the latch arm 414 overcomes the force applied by spring 438 on projection 436, thus causing the projection 436 to move at least partially out of aperture 428 and allowing the movement of the latch arm 414. The inward movement of latch arm 414 is controlled by the link 442, such that contact surface 418 moves inwards and downwards to contact horizontal bar 412. Contact of the contact surface 418 with horizontal bar 412 secures wafer cassette 410 to door 406. When the dome 402 is removed, the force applied by spring 438 on projection 436 drives the projection 436 back into aperture 428 and brings latch arm 414 back to an unlatched position where it does not overlap horizontal bar 412 and the wafer cassette 410 can be removed from the door 406 without interference from latching mechanism 408.

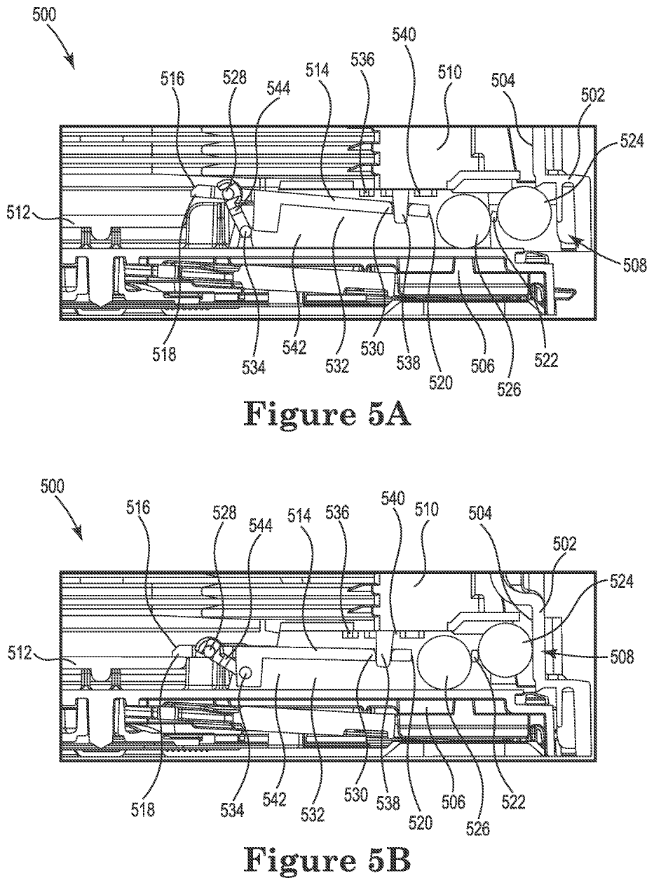

FIG. 5A shows a sectional view of a wafer container when a latching mechanism according to an embodiment is in an unlatched position. Wafer container 500 includes dome 502 including internal surface 504, door 506 including latching mechanism 508, and wafer cassette 510 including horizontal bar 512. The latching mechanism 508 includes a latch arm 514 including a first end 516 having a contact surface 518. Contact surface 518 can be configured to contact wafer cassette 510 at any suitable location such that wafer cassette 510 can be secured, with one non-limiting example being horizontal bar 512. The latch arm 514 further includes a second end 520 having dome contact retainer 522. Dome contact element 524 and guide roller 526 can each be attached to latch arm 514 at dome contact retainer 522. The latch arm 514 further includes an arm link attachment 528 and an aperture 530. The latching mechanism further includes a base 532 defining channel 542. The base 532 can include a base link attachment 534, and a biasing pin 536 including a projection 538 and spring 540. A link 544 is connected to each of the latch arm 514 and the base 532.

The latching mechanism 508 includes a latch arm 514 including a first end 516 having a contact surface 518. Contact surface 518 is configured to contact the wafer cassette 510 when the latching mechanism is in the latched position. The latching mechanism 508 further includes a second end 520, where dome contact element 524 is attached. In an embodiment, a dome contact retainer 522 is at second end 520. Dome contact element 524 is attached to latch arm 514, for example at dome contact retainer 522. Dome contact element 524 can be any suitable contact element, such as an element including a camming surface or a fixed curved surface, a roller, or the like. In an embodiment, dome contact element 524 includes at least two different materials, for example a core including a harder or more rigid core material and a softer or more flexible contact surface. In an embodiment, the contact surface can be overmolded onto the core. In an embodiment, the contact surface material may be selected from one or more of the elastomers of the following list: thermoplastic elastomer, silicone, or the like.

Guide roller 526 is attached to the latch arm 514. Guide roller 526 can assist in guiding the movement of latch arm 514 from the latched position to the unlatched position. Guide roller 526 can be sized such that it contacts only the door 506 when travelling between the latched and unlatched positions. Guide roller 526 includes at least two different materials, for example a core including a harder or more rigid core material and a softer or more flexible contact surface. In an embodiment, the contact surface can be overmolded onto the core. In an embodiment, the contact surface material may be selected from one or more of the elastomers of the following list: thermoplastic elastomer, silicone, or the like.

Arm link attachment 528 is configured to allow attachment of link 544 to latch arm 514. The arm link attachment 528 can be any suitable structure allowing mechanical attachment of the link 544 to latch arm 514, for example a cylinder surrounded by an opening, allowing a clip included in link 544 to attach to arm link attachment 528. In an embodiment, arm link attachment 528 can be a clip or socket configured to receive a portion of link 544. The connection of arm link attachment 528 to link 544 can be such that link 544 and latch arm 514 can rotate relative to one another.

Latch arm 514 includes aperture 530. Aperture 530 is configured to receive projection 538 included in the biasing pin 536. In an embodiment, aperture 530 can have rounded or beveled edges, for example to facilitate insertion of the projection 538 of biasing pin 536 into the aperture 530. Aperture 530 is formed in the latch arm 514 such that the projection 538 of biasing pin 536 can apply force to the latch arm 514, for example to drive the latch arm 514 towards the unlatched state when no force is applied to the latch arm by way of dome contact element 524.

Latching mechanism 508 further includes base 532. Base 532 is provided on door 506. In an embodiment, base 530 has a maximum height above the door 506 of 0.8 inches or less. The base 532 defines channel 542. Channel 542 is configured such that the dome contact element 524 can move in plane with the door 506 through the channel 542. The channel 542 can be sized such that dome contact element 524 only contacts at most one surface of the inside of channel 542 as the dome contact element 524 travels through the channel. The channel 542 can be sized such that the guide roller 526 contacts only one surface of the inside of channel 542 as it travels through the channel. The guide roller 526 and channel 542 can be configured such that the guide roller 526 rolls along door 506 and/or base 532 without rubbing against any other surfaces provided in channel 542. The base 532 includes a base link attachment 534, which can be any suitable structure allowing the rotatable connection of link 544 to the base 532. The base link attachment 534 can be, for example, a cylindrical member with openings surrounding it to allow attachment of a clip, a clip or socket configured to receive a portion of link 544, or the like.

Base 532 further includes a biasing pin 536, configured to return the latch arm 514 to the unlatched position when other forces are not acting on the latch arm 514. The biasing pin 536 includes a projection 538 and spring 540. Projection 538 is configured to be received in aperture 530 provided on latch arm 514. The projection 538 is disposed on spring 540. Spring 540 is configured to allow the deflection of projection 538 when other forces are applied, for example when dome 502 contacts the dome contact element 524, and to provide force returning projection 538 to a position where the latch arm 514 is in an unlatched position. Spring 540 can be any suitable spring, for example one or more spring arms. The spring 540 can be a separate spring attached to base 532 or formed integrally with base 532. The projection 538 can be an element separate from spring 540 and attached thereto, or formed integrally with spring 540. In an embodiment, the base 532, spring 540, and projection 538 are all formed integrally with one another. In an alternative embodiment, the relative positions of aperture 530 and projection 538 can be reversed, with the projection 538 extending from latching arm 514 and the aperture 530 being defined in material attached to or included along the spring 540. In another alternative embodiment, the spring 540 can alternatively be included in the latch arm 514 with one of projection 538 or material defining aperture 530 being disposed on the spring 540, with the other of projection 538 or material defining aperture 530 being provided in a fixed position on base 532.

Link 544 is rotatably attached to latch arm 514 at arm link attachment 528 and rotatably attached to base 532 at base link attachment 534. Link 544 is configured to control the movement of latch arm 514 relative to base 532 when force is applied to the latch arm 514 by contact between the dome 502 and dome contact element 524 and/or by the biasing pin 536. The link 544 can be rigid and have a fixed length. The attachments of link 544 to the latch arm 514 and the base 532 can be at opposing ends of link 544. Link 544 can include any suitable structures to engage with and rotatably attach to arm link attachment 528 and base link attachment 534, such as clips, sockets, or corresponding engagement features such as a ball joint, a cylindrical portion having adjacent openings, or the like.

FIG. 5B shows a sectional view of the wafer container of FIG. 5A when the latching mechanism according to an embodiment is in a latched position. When the dome 502 is attached to the door 506, the internal surface 504 comes into contact with contact dome contact element 524, driving contact dome contact element 524 and guide dome contact element 524 to move within channel 542 and thus also driving latch arm 514 inwards. The contact dome contact element 524 can roll along an upper surface of channel 542, and guide dome contact element can roll along a lower surface of channel 542. In an embodiment, contact dome contact element 524 does not contact the lower surface of channel 542, and guide dome contact element 526 does not contact the upper surface of channel 542. This can reduce or eliminate particle generation from sliding of the dome contact elements 524, 526 along a surface of channel 542. The force moving the latch arm 514 overcomes the force applied by spring 540 on projection 538, thus causing the projection 538 to move at least partially out of aperture 530 and allowing the movement of the latch arm 514. The inward movement of latch arm 514 is controlled by the link 544, such that contact surface 518 moves inwards and downwards to contact horizontal bar 512. Contact of the contact surface 518 with horizontal bar 512 secures wafer cassette 510 to door 506. When the dome 502 is removed, the force applied by spring 540 on projection 538 drives the projection 538 back into aperture 530 and brings latch arm 514 back to an unlatched position where it does not overlap horizontal bar 512 and the wafer cassette 510 can be removed from the door 506 without interference from latching mechanism 508.

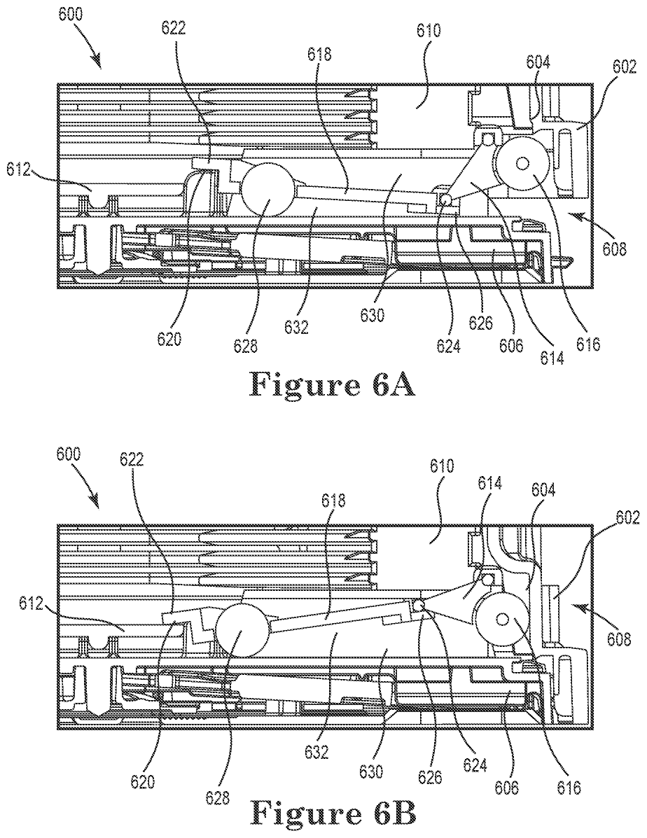

FIG. 6A shows a sectional view of a wafer container when a latching mechanism according to an embodiment is in an unlatched position. Wafer container 600 includes dome 602 having internal surface 604, door 606 including latching mechanism 608, and wafer cassette 610 including horizontal bar 612. The latching mechanism 608 includes a link 614. A dome contact element 616 is attached to the link 614. The link 614 is also attached to a latch arm 618. The latch arm 618 includes a contact surface 620 at a first end 622, a link attachment 624 and a second end 626, and a guide roller 628. The link 614 is also attached to a base 630. The base 630 defines a channel 632.

Link 614 is joined to the base 630 at a first attachment point and to the latch arm 618 at a second attachment point. The attachments are configured such that the link 614 can rotate relative to base 630 and such that the latch arm 618 can rotate relative to the link 614. The link 614 includes dome contact element 616. In an embodiment, the dome contact element 616 is fixed to the link 614 directly, for example being formed integrally with link 614. In an embodiment, dome contact element 616 is a separate element attached to the link 614, for example a roller that is attached to the link 614 by way of a retainer. Dome contact element 616 can be any suitable contact element, such as an element including a camming surface or a fixed curved surface, a roller, or the like. In an embodiment, dome contact element 616 has a relatively rigid core and a relatively flexible contact surface. In an embodiment, link 614 is triangular in shape, with the attachment of link 614 to the latch arm 618 at the first point of the triangle, the attachment of link 614 to base 630 at the second point of the triangle, and the dome contact element 616 at the third point of the triangle. The shape of the link 614 can be such that the mass distribution of link 614 results in the attachment 614 to latch arm 618 being the relatively lowest point of the link 614 when the link 614 is at rest with no other forces acting on the link 614.

Latch arm 618 is attached to the link 614. Latch arm 618 includes contact surface 620 at first end 622. Contact surface 620 can be configured to contact wafer cassette 610 at any suitable location such that wafer cassette 610 can be secured, with one non-limiting example being horizontal bar 612. Link attachment 624 is provided at second end 626, opposite the first end 622. The link attachment can be any suitable feature for attaching latch arm 618 to the link 614 such that the latch arm 618 can rotate relative to link 614. A guide roller 628 is provided along the latch arm 618. The latch arm 618 can be provided at a point closer to the first end 622 than second end 626, such that the mass on the side of guide roller 628 towards second end 626 exceeds the mass on the side of guide roller 628 towards first end 622. The distribution of the mass of latch arm 618 relative to the guide roller 628 can be such that the second end 626 will tend to be pulled downwards by gravity in the absence of other forces acting on the link 614 or latch arm 618. Additionally, in an embodiment a spring is configured to allow deflection of the side of the guide roller 628 when other forces are applied, for example when the dome 604 contacts the dome contact element 616, and returns the side of the guide roller 628 to a position where the latch arm 618 is in an unlatched position.

Base 630 is provided in a fixed position on door 606. The base 630 can be formed integrally with the door 606 or can be a separate element fixed to the door 606 by any suitable means, such as a mechanical connection, adhesive, weld, or the like. In an embodiment, the base 630 is welded to door 606. The base 630 can have a height above the surface of door 606 of 0.8 inches or less. The base 630 can define a channel 632 configured to allow the guide roller 628 to travel within the channel 632. In an embodiment, the guide roller 628 and the channel 632 are sized such that guide roller 628 contacts only one surface of the interior of the channel 632 and can roll along said surface without rubbing against any other surface provided in channel 632. The base 630 can be configured to allow the link 614 to be rotatably attached to the base, for example by providing a clip, a cylindrical region surrounded by openings, or any other suitable feature corresponding to an attachment feature provided on link 614.

FIG. 6B shows a sectional view of the wafer container of FIG. 6A when the latching mechanism according to an embodiment is in a latched position. When internal surface 604 of dome 602 contacts the dome contact element 616, the link 614 is driven to rotate about its connection to the base 630 and drive the latch arm 618 inwards towards the latched position. The rotation of the link 614 also lifts the link attachment 624, raising the second end 626 and lowering the first end 622 as the latch arm 618 rotates about the guide roller 628. Thus, the contact surface 620 is brought inwards and downwards to contact the horizontal bar 612, thus retaining the wafer cassette 610 within the wafer container 600. When the dome 602 is removed and dome contact element 616 is no longer contacted by internal surface 604, the weight of the latch arm 618 and the link 614 cause the link attachment 624 and the attached portion of the link 614 to drop, with resulting rotation of the link 614 drawing the latch arm 618 to the unlatched position where it does not overlap with horizontal bar 612 and allowing the first end 622 to rise by rotation of latch arm 618 about the guide roller 628.

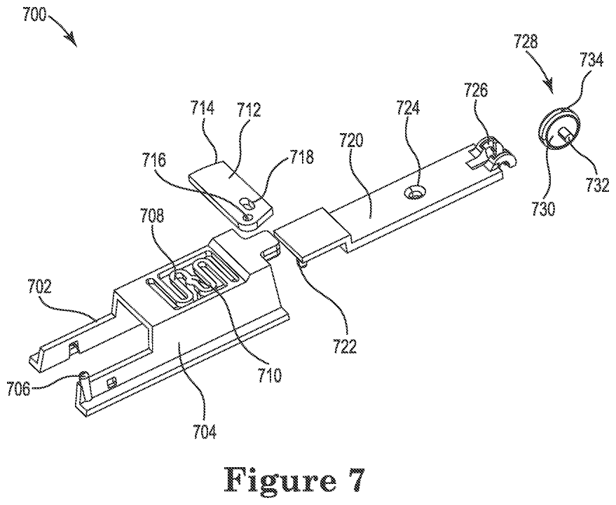

FIG. 7 shows an exploded view of a latching mechanism according to an embodiment. Latching mechanism 700 can be used as the latching mechanism in a wafer container, such as wafer container 100 described above and shown in FIG. 1. Latching mechanism 700 includes base 702. Base 702 includes base body 704, hinge pin 706, biasing spring 708, and biasing pin 710. Latching mechanism 700 further includes latching tab 712. Latching tab 712 includes contact surface 714, hinge aperture 716, and cam aperture 718. Latching mechanism 700 also includes latching arm 720. The latching arm 720 includes a cam projection 722, biasing aperture 724, and roller retention 726. A dome contact element 728 including core 730, axle projection 732, and contact surface 734 can be retained in the roller retention 726.

Base 702 is configured to be joined to a door of a wafer container. In an embodiment, the base 702 can be formed integrally with the door of the wafer container. In an embodiment, the base 702 is joined to the door of the wafer container by a weld. Base 702 includes base body 704. Base body 704 is configured to define a channel capable of accommodating latching arm 720. The base 702 further includes a hinge pin 706. Hinge pin 706 is a pin extending from the base body 704 and sized to be received in hinge aperture 716 of the latching tab 712. In an embodiment, hinge pin 706 can be replaced by an aperture and the hinge aperture 716 can be replaced by a pin, reversing the arrangement of hinge pin 706 and hinge aperture 716 shown in FIG. 7. The hinge pin 706 and hinge aperture 716 are configured to allow the latching tab 712 to be joined to the base 702 such that the latching tab can be rotated in the axis of hinge pin 706 between an unlatched position and a latched position. The base 702 includes biasing spring 708 and biasing pin 710. Biasing pin 710 is disposed along or joined to biasing spring 708 such that the biasing spring provides force to position the biasing pin 710. Biasing pin 710 is a projection configured to be received in biasing aperture 724 formed in the latching arm 720. The biasing spring 708 can be configured such that biasing pin 710 can be deflected when force is applied to the latching arm, for example by way of a dome contacting the dome contact element 728. The spring 708 can then return biasing pin 710 to a position where the biasing pin 710 brings the latching arm 720 into the unlatched position when other force is not being applied to the latching arm 720.

Latching tab 712 is configured to be extended and retracted to respectively retain or release a horizontal bar of a wafer cassette. The latching tab 712 includes contact surface 714, which is configured to contact the wafer cassette in any suitable location capable of securing the wafer cassette when the latching tab 712 is rotated into a latched position. In an embodiment, contact surface 714 is configured to contact a horizontal bar included in the wafer cassette. The latching tab 712 includes a hinge aperture 716 configured to receive the hinge pin 706 such that the latching tab can be rotated relative to the base 702. The latching tab 712 further includes cam aperture 718. The cam aperture 718 is sized and shaped such that the cam projection 722 of the latching arm 720 can be received within the cam aperture 718, and the cam projection 722 can slide within cam aperture 718 in at least one direction that is in plane with the latching tab 712.

The latching arm 720 is configured to drive the latching tab 712 into the latched or unlatched positions. The latching arm includes cam projection 722 at one end of the latching arm 720. The cam projection 722 is configured to be received within cam aperture 718 such that the cam projection 722 can slide within the cam aperture 718 to extend or retract the latching tab 712. Latching arm biasing aperture 724 is disposed along the length of latching arm 720. Latching arm biasing aperture 724 is configured to receive the biasing pin 710. The latching arm biasing aperture 724 is positioned such that the latching arm 720 is in the unlatched position when the biasing pin 710 is received in the latching arm biasing aperture 724 and the spring 708 is in a neutral position. The latching arm biasing aperture 724 can include a rounded or beveled edge. Latching arm 720 can include a dome contact element 728. The dome contact element 728 can be any suitable element for contacting a dome of a wafer container, such that the latching arm 720 can be driven by contact of the dome with the dome contact element 728. In the embodiment shown in FIG. 7, the dome contact element 728 is a roller that is retained within roller retention 726. In the embodiment shown in FIG. 7, the roller used as dome contact element 728 includes core 730, axle projection 732, and contact surface 734. Core 730 can be made of a relatively more rigid material, while a relatively more flexible material is used in contact surface 734. In an embodiment, contact surface 734 is overmolded onto core 730. Axle projection 732 can be received within the roller retention 726 to join the dome contact element 728 to latching arm 720.

When a wafer container including latching mechanism 700 is assembled, contact between the dome of the wafer container and the dome contact element 726 drives the latching arm 720 inwards with respect to the wafer container. The force applied to dome contact element 726 overcomes the force applied to biasing pin 710 by biasing spring 708, and biasing pin exits biasing aperture 724 allowing the latching arm 720 to move inwards. As latching arm 720 moves inwards, cam projection 722 moves within cam aperture 718, driving the latching tab 712 to rotate about hinge pin 706 into the latched position, where contact surface 714 overlaps a horizontal bar of a wafer cassette. The contact surface 714 can thus retain the wafer cassette within the wafer container including the latching mechanism 700. When the dome is removed from the door of the wafer container including latching mechanism 700, the dome no longer applies force to the dome contact element and biasing pin 710 can be driven into biasing aperture 724 by the biasing spring 708, moving the latching arm 720 outward, moving cam projection 722 within cam aperture 718 so as to retract the latching tab 712 into the unlatched position, where it does not overlap with the horizontal bar of the wafer cassette.

Aspects:

It is understood that any of aspects 1-11 can be combined with any of aspects 12-20.

Aspect 1. A wafer container, comprising:
a dome defining a space configured to accommodate a wafer cassette, the dome including an inner surface and a door opening; and
a door configured to be received in the door opening, the door including a latching mechanism,
wherein the latching mechanism includes a dome contact and a cassette contact, and the latching mechanism is configured such that when the inner surface of the dome contacts the dome contact, the cassette contact is driven to contact the wafer cassette, and when the inner surface of the dome does not contact the dome contact, the latch does not overlap with the wafer cassette.

Aspect 2. The wafer container according to aspect 1, wherein the dome contact is a roller element.

Aspect 3. The wafer container according to aspect 2, wherein the roller element includes a core made of a first material and an outer portion made of a second material, the second material relatively softer than the first material.

Aspect 4. The wafer container according to any of aspects 1-3, wherein the cassette contact is configured to contact the wafer cassette at a horizontal bar included in the wafer cassette.

Aspect 5. The wafer container according to any of aspects 1-4, wherein the latching mechanism includes:
a base;
a latching arm, wherein the dome contact is disposed at a first end of the latching arm and the cassette contact is disposed at a second end of the latching arm; and
a plurality of links, each link rotatably connected to each of the base and the latching arm.

Aspect 6. The wafer container according to aspect 5, wherein the base is joined to the door.

Aspect 7. The wafer container according to any of aspects 5-6, further comprising a biasing spring configured to contact the latching arm.

Aspect 8. The wafer container according to any of aspects 1-4, wherein the latching mechanism includes:
a base, the base including a channel configured to receive the dome contact;
a latching arm including the cassette contact; and
a link, the link rotatably connected to each of the base and the latching arm,
wherein the base includes a pin configured to interface with the latching arm.

Aspect 9. The wafer container according to aspect 8, wherein the latching mechanism further comprises a guide roller, the guide roller disposed in the channel.

Aspect 10. The wafer container according to any of aspects 1-4 wherein the latching mechanism includes:
a base, the base defining a channel;
a latching arm including the cassette contact;
a link, wherein the dome contact is attached to the link and the link is rotatably connected to each of the base and the latching arm; and
a guide roller, the guide roller attached to the latching arm, the guide roller configured to travel within the channel.

Aspect 11. The wafer container of claim 1, wherein the latching mechanism includes:
a base;
a driving arm, wherein the dome contact is attached to the driving arm; and
a latching arm rotatably connected to the base, the latching arm including the cassette contact wherein the driving arm and the latching arm are joined by a cam structure, the cam structure including a projection and a groove and configured so as to drive rotation of the latching arm between an unlatched position and a latched position.

Aspect 12. A method of securing a wafer cassette within a container, comprising driving a latching mechanism by way of contact between a dome contact of said latching mechanism and an inner surface of a dome such that a cassette contact is brought into contact with the wafer cassette.

Aspect 13. The method according to aspect 12, further comprising retracting the cassette contact such that the cassette contact does not overlap the wafer cassette when the dome is removed from contact with the dome contact.

Aspect 14. The method according to any of aspects 12-13, wherein the latching mechanism is included in a door of the container.

Aspect 15. The method according to any of aspects 12-14, wherein the cassette contact contacts the wafer cassette at a horizontal bar included in the wafer cassette.

Aspect 16. The method according to any of aspects 12-15, wherein the latching mechanism includes:
a base;
a latching arm, wherein the dome contact is disposed at a first end of the latching arm and the cassette contact is disposed at a second end of the latching arm; and
a plurality of links, each link rotatably connected to each of the base and the latching arm.

Aspect 17. The method according to any of aspects 12-15, wherein the latching mechanism includes:
a base, the base including a channel configured to receive the dome contact;
a latching arm including the cassette contact; and
a link, the link rotatably connected to each of the base and the latching arm,
wherein the base includes a pin configured to interface with the latching arm.

Aspect 18. The method according to aspect 17, wherein the latching mechanism further comprises a guide roller disposed in the channel.

Aspect 19. The method according to any of aspects 12-15, wherein the latching mechanism includes:
a base, the base defining a channel;
a latching arm including the cassette contact;
a link, wherein the dome contact is attached to the link and the link is rotatably connected to each of the base and the latching arm; and
a guide roller, the guide roller attached to the latching arm, the guide roller configured to travel within the channel.

Aspect 20. The method according to any of aspects 12-15, wherein the latching mechanism includes:
a base;
a driving arm, wherein the dome contact is attached to the driving arm; and
a latching arm rotatably connected to the base, the latching arm including the cassette contact wherein the driving arm and the latching arm are joined by a cam structure, the cam structure including a projection and a groove, the cam configured to drive rotation of the latching arm between an unlatched position and a latched position.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. A wafer container, comprising:
a dome defining a space configured to accommodate a wafer cassette, the dome including an inner surface and a door opening; and
a door configured to be received in the door opening, the door including a latching mechanism,
wherein the latching mechanism includes a dome contact and a cassette contact, and the latching mechanism is configured such that when the inner surface of the dome is in contact with the dome contact, the cassette contact is driven to contact the wafer cassette, and when the inner surface of the dome does not contact the dome contact, the latch does not overlap with the wafer cassette.

2. The wafer container of claim 1, wherein the dome contact is a roller element.

3. The wafer container of claim 2, wherein the roller element includes a core made of a first material and an outer portion made of a second material, the second material relatively softer than the first material.

4. The wafer container of claim 1, wherein the cassette contact is configured to contact the wafer cassette at a horizontal bar included in the wafer cassette.

5. The wafer container of claim 1, wherein the latching mechanism includes:
a base;
a latching arm, wherein the dome contact is disposed at a first end of the latching arm and the cassette contact is disposed at a second end of the latching arm; and
a plurality of links, each link rotatably connected to each of the base and the latching arm.

6. The wafer container of claim 5, wherein the base is joined to the door.

7. The wafer container of claim 5, further comprising a biasing spring configured to contact the latching arm.

8. The wafer container of claim 1, wherein the latching mechanism includes:
a base, the base including a channel configured to receive the dome contact;
a latching arm including the cassette contact; and
a link, the link rotatably connected to each of the base and the latching arm,
wherein the base includes a pin configured to interface with the latching arm.

9. The wafer container of claim 8, wherein the latching mechanism further comprises a guide roller, the guide roller disposed in the channel.

10. The wafer container of claim 1, wherein the latching mechanism includes:
a base, the base defining a channel;
a latching arm including the cassette contact;
a link, wherein the dome contact is attached to the link and the link is rotatably connected to each of the base and the latching arm; and
a guide roller, the guide roller attached to the latching arm, the guide roller configured to travel within the channel.

11. The wafer container of claim 1, wherein the latching mechanism includes:
a base;
a driving arm, wherein the dome contact is attached to the driving arm; and
a latching arm rotatably connected to the base, the latching arm including the cassette contact wherein the driving arm and the latching arm are joined by a cam structure, the cam structure including a projection and a groove and configured so as to drive rotation of the latching arm between an unlatched position and a latched position.

12. A method of securing a wafer cassette within a container, comprising driving a latching mechanism by way of contact between a dome contact of said latching mechanism and an inner surface of a dome such that a cassette contact is brought into contact with the wafer cassette.

13. The method of claim 12, further comprising retracting the cassette contact such that the cassette contact does not overlap the wafer cassette when the dome is removed from contact with the dome contact.

14. The method of claim 12, wherein the latching mechanism is included in a door of the container.

15. The method of claim 12, wherein the cassette contact contacts the wafer cassette at a horizontal bar included in the wafer cassette.

16. The method of claim 12, wherein the latching mechanism includes:
a base;
a latching arm, wherein the dome contact is disposed at a first end of the latching arm and the cassette contact is disposed at a second end of the latching arm; and
a plurality of links, each link rotatably connected to each of the base and the latching arm.

17. The method of claim 12, wherein the latching mechanism includes:
a base, the base including a channel configured to receive the dome contact;
a latching arm including the cassette contact; and
a link, the link rotatably connected to each of the base and the latching arm,
wherein the base includes a pin configured to interface with the latching arm.

18. The method of claim 17, wherein the latching mechanism further comprises a guide roller disposed in the channel.

19. The method of claim 11, wherein the latching mechanism includes:
a base, the base defining a channel;
a latching arm including the cassette contact;
a link, wherein the dome contact is attached to the link and the link is rotatably connected to each of the base and the latching arm; and
a guide roller, the guide roller attached to the latching arm, the guide roller configured to travel within the channel.

20. The method of claim 11, wherein the latching mechanism includes:
a base;
a driving arm, wherein the dome contact is attached to the driving arm; and
a latching arm rotatably connected to the base, the latching arm including the cassette contact wherein the driving arm and the latching arm are joined by a cam structure, the cam structure including a projection and a groove, the cam configured to drive rotation of the latching arm between an unlatched position and a latched position.
